(19) United States
(12) Patent Application Publication
(10) Pub. No.: US 2010/0080313 A1
(43) Pub. Date: Apr. 1, 2010

(54) APPARATUS AND METHOD FOR SUPPORTING IN-BAND VENUE-CAST ON A FORWARD LINK ONLY (FLO) NETWORK USING PILOT INTERFERENCE CANCELLATION

(75) Inventor: RAGHURAMAN KRISHNAMOORTHI, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/569,759

(22) Filed: Sep. 29, 2009

Related U.S. Application Data
(60) Provisional application No. 61/101,667, filed on Sep. 30, 2008.

(51) Int. Cl. H04K 1/10; H03D 1/04; H04L 27/00

(52) U.S. Cl. 375/260; 375/346; 375/295

(57) ABSTRACT

An apparatus and method for supporting in-band venue-cast comprising receiving a waveform with macro-cast contents introduced into a first symbol space in a superframe for wide area and local area services, at least one pilot signal introduced into a second symbol space in the superframe and venue-cast contents also introduced into the second symbol space, wherein the macro-cast contents and the at least one pilot signal are transmitted by a macro transmitter, and the venue-cast contents are transmitted by a venue transmitter; performing pilot interference cancellation to null the at least one pilot signal in the second symbol space; and extracting the venue-cast contents from the received waveform. In one aspect, the apparatus and method comprises determining a symbol space where pilots associated with macro transmission are scheduled for transmission; introduces venue-cast contents into the symbol space to form a waveform; and transmits the waveform to a predetermined venue site.

### CLAIM OF PRIORITY UNDER 35 U.S.C. §119

The present Application for Patent claims priority to Provisional Application No. 61/101,667 entitled “Venue-Cast Physical Architecture With Dedicated Bandwidth” filed Sep. 30, 2008, and assigned to the assignee hereof and hereby expressly incorporated by reference herein.

### FIELD

This disclosure relates generally to apparatus and methods for pilot interference cancellation in a wireless communication system. More particularly, the disclosure relates to pilot interference cancellation in a Forward Link Only (FLO) wireless network in support of in-band venue-cast.

### BACKGROUND

Wireless communication systems deliver various communication services to mobile users which are separated and/or moving from the fixed telecommunications infrastructure. Wireless systems typically use radio transmission technology to allow mobile user devices to access various base stations in a wireless communication network, often in a cellular geometry. The base stations, in turn, are connected to mobile switching centers which route connections to and from the mobile user devices to other users on different communications networks such as the public switched telephony network (PSTN), Internet, or the wireless network itself. In this manner, users that are away from fixed sites or are on the move may receive a variety of communication services such as voice telephony, paging, messaging, email, data transfers, video, Web browsing, etc.

Wireless users use a variety of communication protocols to share the scarce radio spectrum allocated for wireless communication services. One important physical layer protocol relates to the access technique a mobile user device employs to connect to the wireless communications network. Various access methods include frequency division multiple access (FDMA), time division multiple access (TDMA), code division multiple access (CDMA), and orthogonal frequency division multiplex (OFDM). OFDM is increasingly popular in terrestrial wireless communication systems because its multicarrier format mitigates multipath distortions while providing flexible capacity for user needs. OFDM utilizes a plurality of carriers spaced apart in the frequency domain such that data modulated on each carrier is orthogonal (and thus independent) to the others. OFDM has the advantage of being conveniently modulated and demodulated through very efficient Fast Fourier Transform (FFT) techniques in both the transmitter and receiver.

### SUMMARY

Disclosed is an apparatus and method for supporting in-band venue-cast on a FLO network using pilot interference cancellation. According to one aspect, a method for supporting in-band venue-cast on a FLO network using pilot interference cancellation comprising receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter; performing pilot interference cancellation to null the at least one pilot signal in the second symbol space; and extracting the venue-cast contents from the received waveform.

According to another aspect, a method for supporting in-band venue-cast on a FLO network using pilot interference cancellation comprising determining a symbol space of a superframe where pilots associated with macro transmission are scheduled for transmission; introducing venue-cast contents into the symbol space of the superframe to form a waveform; and transmitting the waveform to a predetermined venue site.

According to another aspect, a receiving device for supporting in-band venue-cast on a FLO network using pilot interference cancellation comprising a receiver using an antenna for receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter; a memory unit coupled to the receiver for storing the waveform; and a processor coupled with the memory unit, the processor for performing pilot interference cancellation to null the at least one pilot signal in the second symbol space, and for extracting the venue-cast contents from the received waveform.

According to another aspect, a venue transmitter for supporting in-band venue-cast on a FLO network using pilot interference cancellation comprising a processor for determining a symbol space of a superframe where pilots associated with macro transmission are scheduled for transmission, and for introducing venue-cast contents into the symbol space of the superframe to form a waveform; and an antenna coupled to the processor for transmitting the waveform to a predetermined venue site.

According to another aspect, a receiving apparatus for supporting in-band venue-cast on a FLO network using pilot interference cancellation comprising means for receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter; means for performing pilot interference cancellation to null the at least one pilot signal in the second symbol space; and means for extracting the venue-cast contents from the received waveform.

According to another aspect, a transmitting apparatus for supporting in-band venue-cast on a FLO network using pilot interference cancellation comprising means for determining a symbol space of a superframe where pilots associated with macro transmission are scheduled for transmission; means for introducing venue-cast contents into the symbol space of the superframe to form a waveform; and means for transmitting the waveform to a predetermined venue site.

According to another aspect, a computer-readable medium storing a computer program, wherein execution of the computer program is for receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter; performing pilot interference cancellation to null the at least one pilot signal in the second symbol space; and extracting the venue-cast contents from the received waveform.

According to another aspect, a computer-readable medium storing a computer program, wherein execution of the computer program is for determining a symbol space of a superframe where pilots associated with macro transmission are scheduled for transmission; introducing venue-cast contents into the symbol space of the superframe to form a waveform; and transmitting the waveform to a predetermined venue site.

Advantages of the present disclosure include efficient implementation of venue-cast within an existing FLO framework, fine granularity of partition of resources between FLO services and venue services, integrated reception of both FLO services and venue services with minimal receiver changes. Another advantage is that the venue transmissions are decoupled from the macro transmissions. The venue transmitter does not transmit any data during the macro data portion of the frame. Therefore venue transmitters do not need a backhaul.

It is understood that other aspects will become readily apparent to those skilled in the art from the following detailed description, wherein it is shown and described various aspects by way of illustration. The drawings and detailed description are to be regarded as illustrative in nature and not as restrictive.

### BRIEF DESCRIPTION OF THE DRAWINGS

FIG. 1 is a block diagram illustrating an example access node/user equipment (UE) system.

FIG. 2a illustrates an example of a wireless communications system that supports a plurality of users.

FIG. 2b illustrates an example wireless broadcasting system which incorporates in-band venue services.

FIG. 3 illustrates an example transmission format of a mobile broadcasting service which uses orthogonal frequency division multiplex (OFDM).

FIG. 4 illustrates an example transmission format of a mobile broadcasting service which uses orthogonal frequency division multiplex (OFDM) where venue area broadcast services are transmitted in the portion of the superframe where scrambled pilots are typically scheduled for macro network usage.

FIG. 5a illustrates an example FLO superframe structure of 1 second duration showing the interleaving of wide-area, local-area, and venue-area pilots and data in the time domain.

FIG. 5b illustrates an example flow diagram for pilot interference cancellation to enable reception of venue-cast contents.

FIG. 6 illustrates an example flow diagram for supporting in-band venue-cast on a FLO network using pilot interference cancellation from the viewpoint of a receiving device.

FIG. 7 illustrates an example flow diagram for supporting in-band venue-cast on a FLO network using pilot interference cancellation from the viewpoint of a venue transmitter.

FIG. 8 illustrates an example of a device comprising a processor in communication with a memory for executing the processes for supporting in-band venue-cast on a FLO network using pilot interference cancellation.

FIGS. 9 and 10 illustrate two examples of two devices suitable for supporting in-band venue-cast on a FLO network using pilot interference cancellation.

### DETAILED DESCRIPTION

The detailed description set forth below in connection with the appended drawings is intended as a description of various aspects of the present disclosure and is not intended to represent the only aspects in which the present disclosure may be practiced. Each aspect described in this disclosure is provided merely as an example or illustration of the present disclosure, and should not necessarily be construed as preferred or advantageous over other aspects. The detailed description includes specific details for the purpose of providing a thorough understanding of the present disclosure. However, it will be apparent to those skilled in the art that the present disclosure may be practiced without these specific details. In some instances, well-known structures and devices are shown in block diagram form in order to avoid obscuring the concepts of the present disclosure. Acronyms and other descriptive terminology may be used merely for convenience and clarity and are not intended to limit the scope of the present disclosure.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

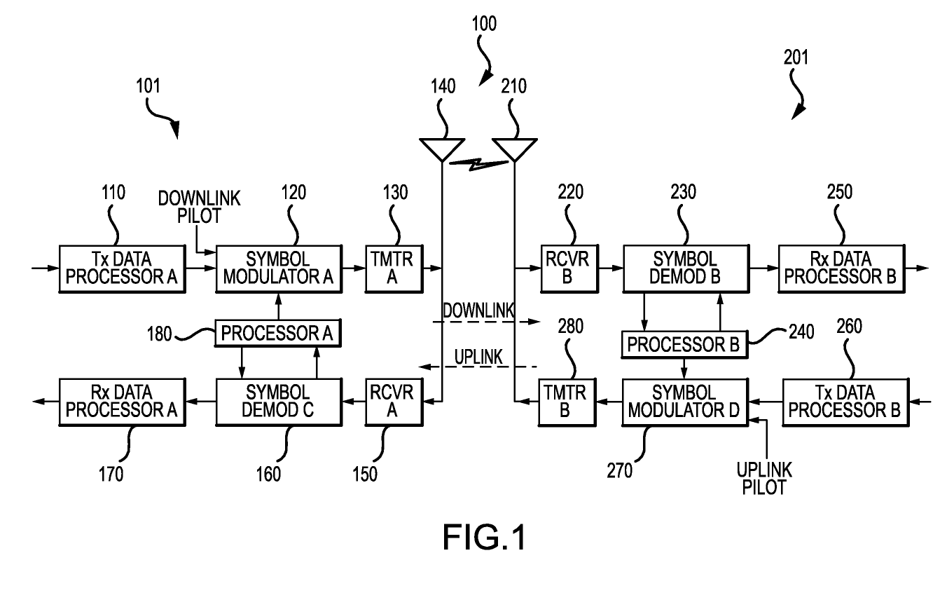

FIG. 1 is a block diagram illustrating an example access node/user equipment (UE) system 100. One skilled in the art would understand that the example access node/UE system 100 illustrated in FIG. 1 may be implemented in an FDMA environment, an OFDMA environment, a CDMA environment, a WCDMA environment, a TDMA environment, a SDMA environment or any other suitable wireless environment.

The access node/UE system 100 includes an access node 101 (e.g., base station, macro transmitter, venue transmitter) and a user equipment or UE 201 (e.g., wireless communication device, receiving device). In the downlink leg, the access node 101 includes a transmit (TX) data processor A 110 that accepts, formats, codes, interleaves and modulates (or symbol maps) traffic data and provides modulation symbols (e.g., data symbols). The TX data processor A 110 is in communication with a symbol modulator A 120. The symbol modulator A 120 accepts and processes the data symbols and downlink pilot symbols and provides a stream of symbols. In one aspect, it is the symbol modulator A 120 that modulates (or symbol maps) traffic data and provides modulation symbols (e.g., data symbols). In one aspect, symbol modulator A 120 is in communication with processor A 180 which provides configuration information. Symbol modulator A 120 is in communication with a transmitter unit (TMTR) A 130. The symbol modulator A 120 multiplexes the data symbols and downlink pilot symbols and provides them to the transmitter unit A 130.

Each symbol to be transmitted may be a data symbol, a downlink pilot symbol or a signal value of zero. The downlink pilot symbols may be sent continuously in each symbol period. In one aspect, the downlink pilot symbols are frequency division multiplexed (FDM). In another aspect, the downlink pilot symbols are orthogonal frequency division multiplexed (OFDM). In yet another aspect, the downlink pilot symbols are code division multiplexed (CDM). In one aspect, the transmitter unit A 130 receives and converts the stream of symbols into one or more analog signals and further conditions, for example, amplifies, filters and/or frequency upconverts the analog signals, to generate an analog downlink signal suitable for wireless transmission. The analog downlink signal is then transmitted through antenna 140.

In the downlink leg, the UE 201 (e.g., wireless communication device, receiving device) includes antenna 210 for receiving the analog downlink signal and inputting the analog downlink signal to a receiver unit (RCVR) B 220. In one aspect, the receiver unit B 220 conditions, for example, filters, amplifies, and frequency downconverts the analog downlink signal to a first “conditioned” signal. The first “conditioned” signal is then sampled. The receiver unit B 220 is in communication with a symbol demodulator B 230. The symbol demodulator B 230 demodulates the first “conditioned” and “sampled” signal (e.g., data symbols) outputted from the receiver unit B 220. One skilled in the art would understand that an alternative is to implement the sampling process in the symbol demodulator B 230. The symbol demodulator B 230 is in communication with a processor B 240. Processor B 240 receives downlink pilot symbols from symbol demodulator B 230 and performs channel estimation on the downlink pilot symbols. In one aspect, the channel estimation is the process of characterizing the current propagation environment. The symbol demodulator B 230 receives a frequency response estimate for the downlink leg from processor B 240. The symbol demodulator B 230 performs data demodulation on the data symbols to obtain data symbol estimates on the downlink path. The data symbol estimates on the downlink path are estimates of the data symbols that were transmitted. The symbol demodulator B 230 is also in communication with a RX data processor B 250.

The RX data processor B 250 receives the data symbol estimates on the downlink path from the symbol demodulator B 230 and, for example, demodulates (i.e., symbol demaps), deinterleaves and/or decodes the data symbol estimates on the downlink path to recover the traffic data. In one aspect, the processing by the symbol demodulator B 230 and the RX data processor B 250 is complementary to the processing by the symbol modulator A 120 and TX data processor A 110, respectively.

In the uplink leg, the UE 201 includes a TX data processor B 260. The TX data processor B 260 accepts and processes traffic data to output data symbols. The TX data processor B 260 is in communication with a symbol modulator D 270. The symbol modulator D 270 accepts and multiplexes the data symbols with uplink pilot symbols, performs modulation and provides a stream of symbols. In one aspect, symbol modulator D 270 is in communication with processor B 240 which provides configuration information. The symbol modulator D 270 is in communication with a transmitter unit B 280. In a forward link only (FLO) system, there is no uplink leg since the direction of the broadcast is from the access node 101 (e.g., base station, macro transmitter, venue transmitter) to the UE 201 (e.g., wireless communication device, receiving device). However, a communication system may include a FLO component plus a return link with multiple access capabilities, i.e., the uplink leg as disclosed herein.

Each symbol to be transmitted may be a data symbol, an uplink pilot symbol or a signal value of zero. The uplink pilot symbols may be sent continuously in each symbol period. In one aspect, the uplink pilot symbols are frequency division multiplexed (FDM). In another aspect, the uplink pilot symbols are orthogonal frequency division multiplexed (OFDM). In yet another aspect, the uplink pilot symbols are code division multiplexed (CDM). In one aspect, the transmitter unit B 280 receives and converts the stream of symbols into one or more analog signals and further conditions, for example, amplifies, filters and/or frequency upconverts the analog signals, to generate an analog uplink signal suitable for wireless transmission. The analog uplink signal is then transmitted through antenna 210.

The analog uplink signal from UE 201 is received by antenna 140 and processed by a receiver unit A 150 to obtain samples. In one aspect, the receiver unit A 150 conditions, for example, filters, amplifies and frequency downconverts the analog uplink signal to a second “conditioned” signal. The second “conditioned” signal is then sampled. The receiver unit A 150 is in communication with a symbol demodulator C 160. One skilled in the art would understand that an alternative is to implement the sampling process in the symbol demodulator C 160. The symbol demodulator C 160 performs data demodulation on the data symbols to obtain data symbol estimates on the uplink path and then provides the uplink pilot symbols and the data symbol estimates on the uplink path to the RX data processor A 170. The data symbol estimates on the uplink path are estimates of the data symbols that were transmitted. The RX data processor A 170 processes the data symbol estimates on the uplink path to recover the traffic data transmitted by the wireless communication device 201. The symbol demodulator C 160 is also in communication with processor A 180. Processor A 180 performs channel estimation for each active terminal transmitting on the uplink leg. In one aspect, multiple terminals may transmit pilot symbols concurrently on the uplink leg on their respective assigned sets of pilot subbands where the pilot subband sets may be interlaced.

Processor A 180 and processor B 240 direct (i.e., control, coordinate or manage, etc.) operation at the access node 101 (e.g., base station) and at the UE 201, respectively. In one aspect, either or both processor A 180 and processor B 240 are associated with one or more memory units (not shown) for storing of program codes and/or data. In one aspect, either or both processor A 180 or processor B 240 or both perform computations to derive frequency and impulse response estimates for the uplink leg and downlink leg, respectively.

In one aspect, the access node/UE system 100 is a multiple-access system. For a multiple-access system (e.g., frequency division multiple access (FDMA), orthogonal frequency division multiple access (OFDMA), code division multiple access (CDMA), time division multiple access (TDMA), space division multiple access (SDMA), etc.), multiple terminals transmit concurrently on the uplink leg, allowing access to a plurality of UEs. In one aspect, for the multiple-access system, the pilot subbands may be shared among different terminals. Channel estimation techniques are used in cases where the pilot subbands for each terminal span the entire operating band (possibly except for the band edges). Such a pilot subband structure is desirable to obtain frequency diversity for each terminal.

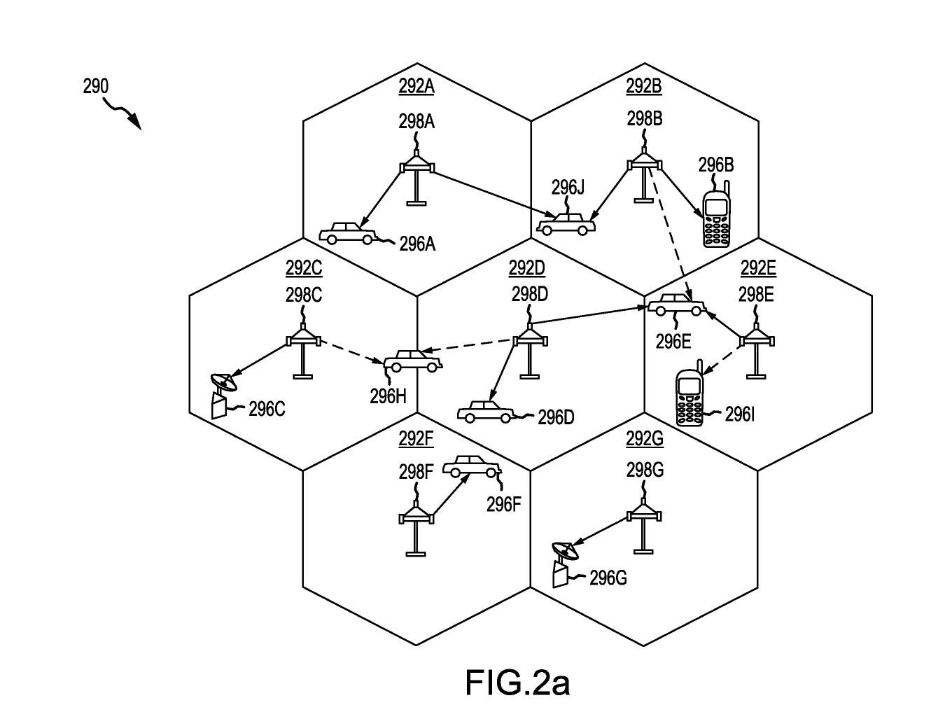

FIG. 2a illustrates an example of a wireless communications system 290 that supports a plurality of users (e.g., mobile user devices 296B, 296I). In FIG. 2a, reference numerals 292A to 292G refer to cells, reference numerals 298A to 298G refer to base stations (BS) or base transceiver station (BTS) and reference numerals 296A to 296J refer to access User Equipments (UE) or mobile user devices. Cell size may vary. Any of a variety of algorithms and methods may be used to schedule transmissions in system 290. System 290 provides communication for a number of cells 292A through 292G, each of which is serviced by a corresponding base station 298A through 298G, respectively.

In one example, a wireless communication system provides mobile broadcasting services to mobile user devices. Broadcasting is a transmission method from one transmitter to many receivers simultaneously in a coverage area. One example of a mobile broadcasting standard is known as FLO (Forward Link Only). In one aspect, the FLO physical layer employs OFDM with 4096 carriers over the system bandwidth, with a much higher data capacity than other systems. Mobile broadcasting services include real-time video and audio streams, non-real time video and audio clips, data content, etc. In one example, the FLO OFDM symbol time is 833.33 microseconds, comprised of 738.02 μs of bearer traffic, 3.06 μs of window, and 92.25 μs of cyclic prefix. A cyclic prefix is a repetition of the end of an OFDM symbol at the beginning of the next OFDM symbol to mitigate multipath interference.

FIG. 2b illustrates an example wireless broadcasting system which incorporates in-band venue services. Shown in the service coverage area is a venue site which contains a venue transmitter and antenna and venue servers to provide venue-cast contents or other contents, such as advertisements, datacasts, etc. In addition, the service coverage area includes one or more macro transmitters and antennas to broadcast macro-cast contents. Also illustrated is a macro network management center for managing the macro services and the macro-cast contents. In one aspect, the macro network management center is connected to a third generation wireless radio access network (3G RAN) via an Internet Protocol (IP) network.

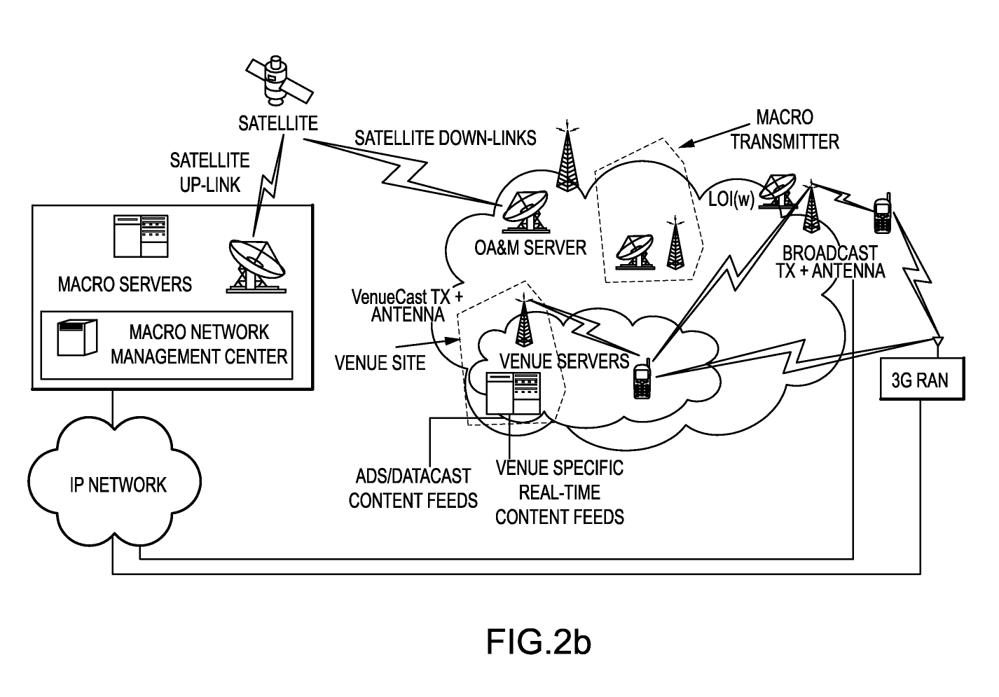

FIG. 3 illustrates an example transmission format of a mobile broadcasting service which uses orthogonal frequency division multiplex (OFDM). The format shows symbols, in the time domain, along the horizontal axis and slots, in the frequency domain, along the vertical axis. As illustrated in FIG. 3, the symbols refer to OFDM symbols in time and the slots refer to groups of subcarriers in frequency. As a multiplexing technique, different services may be simultaneously broadcast using different groups of symbols and slots.

For example, FIG. 3 shows a multiplexing arrangement with 9 symbols per superframe where the first five symbols are dedicated for wide area services, the next two symbols are used for local area services, and the last two symbols are used for scrambled pilots. In one aspect, venue area services may be introduced into the symbol space normally used for scrambled pilots. The combination of wide area services and local area services may be referred as macro network services (“macro services”), while the venue area services (“venue services”) are intended only for a specific venue. In this arrangement, the macro service receiving devices use only a portion of the frame. Since the macro service receiving devices decode only macro service data, existing (i.e., legacy) macro receiving devices do not process data from the venue service portion of the frame. In one aspect, the macro services are broadcast by a macro transmitter while the venue services are broadcast by a venue transmitter. In one example, the power level of the macro transmitter is higher at the symbol spaces for the macro services than the symbol spaces for the venue services.

Delivery of services to specific venue areas (i.e., venue services) increases efficiency in reaching targeted audience, and as such, increases business value of the broadcast. For example, electronic coupons can be broadcast (i.e., sent) to receiving devices of potential shoppers in a defined venue location. In another example, streaming videos can introduce amenities available in a shopping mall. In another example, advertisements from different vendors can be broadcast to attendees at a convention center. One skilled in the art would understand that the examples given here are not an exclusive listing.

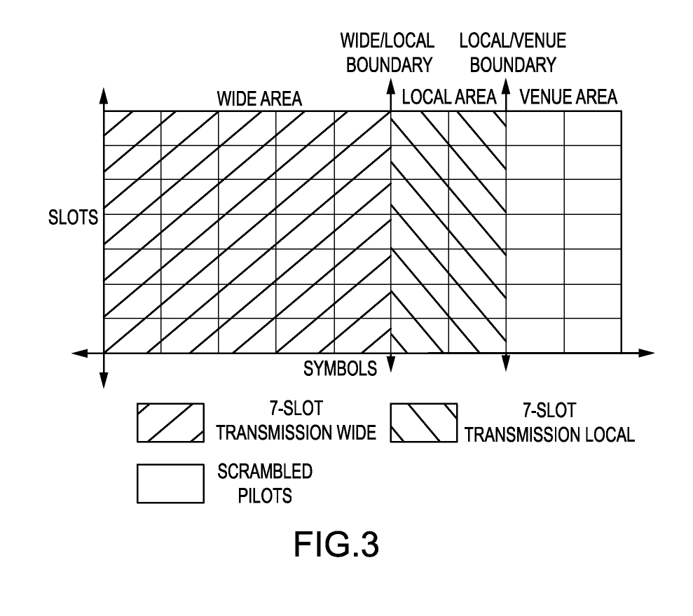

FIG. 4 illustrates an example transmission format of a mobile broadcasting service which uses orthogonal frequency division multiplex (OFDM) where venue services are transmitted in the portion of the superframe where scrambled pilots are typically scheduled for usage with the macro services. In one aspect, a venue transmitter is placed at the desired venue site to broadcast venue-cast contents. A given receiving device at the venue site would receive the macro-cast contents from a macro transmitter and the venue-cast contents from the venue transmitter in the same frequency band. Since the venue-cast contents are broadcast in the portion of the superframe where scrambled pilots are typically scheduled, the receiving device includes the ability to decode the venue-cast contents without pilots.

FIGS. 3 and 4 illustrate the partition between the portions of the superframe dedicated for macro network services (i.e., wide area services and local area services) and for venue area services. Essentially, a fraction of the OFDM data symbols are blanked out from the broadcasted waveform from the macro-cast transmitter (“macro waveform”) which are then filled by transmissions from the venue transmitter for venue-cast content.

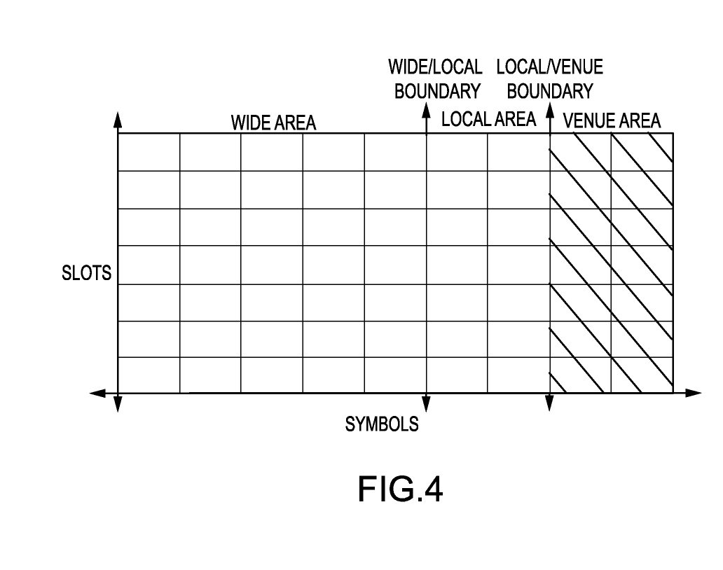

FIG. 5a illustrates an example FLO superframe structure of 1 second duration showing the interleaving of wide-area, local-area, and venue-area pilots, and wide-area, local-area, and venue-area data in the time domain. In one example, interference cancellation is performed at the physical layer of a network protocol stack to ensure that macro transmitters which are higher power are not turned off, while the venue transmitters which are lower power are turned on and off as needed. In one example, the macro transmitters send a predetermined (i.e., known) pattern, designated as scrambled pilots, during the venue portion of the frame. In one aspect, the predetermined pattern includes a position pilot channel (PPC) which can be used for determining the absence or presence of venue-cast contents. In one example, the position pilot channel is divided into two parts: a network position pilot channel (NETWORK-PPC) and a venue position pilot channel (VENUE-PPC). The VENUE-PPC portion is dedicated for venue transmitters and is further sub-divided into two parts (V-PPC and R-PPC):
V-PPC: The V-PPC symbol is dedicated for transmission of a venue transmitter identification and is used to determine the scrambling sequence used for venue transmission and the presence or absence of venue-cast contents.
R-PPC: The R-PPC symbols are used for transmitting venue overhead information and contain information identifying the starting point of the venue service portion (i.e., symbol space) in the superframe.
   In addition, the venue signal may contain transition signals, known as V-TPC, as shown in FIG. 5a, which aid in the convergence of the automatic gain control (AGC) loops in the receiver and to bootstrap the channel estimation. In one example, the V-TPC signals are present at the beginning and end of the venue portion of each frame.

In one example, the macro transmitters operate in inactive PPC mode during the VENUE-PPC symbol transmission period. To receive venue-cast contents, receiving devices determine the presence of venue using the V-PPC symbol and obtain venue overhead information and control information using the R-PPC symbols. In this example, only the macro transmitter transmits the synchronization pilots (TDM1 and TDM2). The macro transmitter requires no changes for supporting venue services. In one example, the macro signal power may be reduced during the venue portion of the frame. Although it may not be possible to turn the macro transmitters off and on, reducing their transmitted power level may be feasible.

In one example, to decode the venue signal, the receiving devices needs to support pilot interference cancellation on the venue portion of the frame and independent scrambling of the wide, local, and venue portions of the frame. Many techniques for pilot interference cancellation are well known in the art and can be used in conjunction with the present disclosure without affecting its scope or intent.

In one aspect, in order for the receiving device to detect venue-cast transmission efficiently in the presence of macro-cast transmission, venue overhead information symbols that identify venue-cast transmission position and characteristics are included in the superframe. In one example, the venue overhead information symbol is included with the venue-cast contents.

FIG. 5b illustrates an example flow diagram for pilot interference cancellation to enable reception of venue-cast contents. As illustrated, the OFDM symbols are accepted by the receiver and then interference cancellation is performed on the macro pilot. The resulting signal (i.e., venue signal plus noise) is then sent to the venue signal decoder for performing venue signal decoding. The venue-cast contents are carried by the venue signal. Specifically, using the subscript M for the macro pilot and V for the venue signal, the received data in the venue portion of the superframe can be written as:

R(k)=H_{M}(k)·P_{M}(k)+Hᵥ(k)Xᵥ(k)+W(k)
where
R(k) is the received signal on sub-carrier k (in the frequency domain)
P_{M}(k) is the macro pilot
H_{M}(k) is the macro channel matrix
Xᵥ(k) is the venue signal at the venue transmitter
Hᵥ(k) is the venue channel matrix
W(k) is additive noise.

Since the macro pilot is known at the receiver, the first step is the cancellation of the macro pilot. This is accomplished by estimating the macro channel estimate. The estimation is done as follows:
1. Perform Fast Fourier Transform (FFT) on the received signal to obtain the signal R(k)
2. Perform macro pilot descrambling of the signal R(k) to obtain frequency domain channel estimates given by:

H_{M}(k)+Hᵥ(k)Xᵥ(k)P_{M}*(k)+W(k)P_{M}*(k)
3. Perform an Inverse Fast Fourier Transform (IFFT) on the macro pilot to obtain time domain channel estimates
4. Filter the time domain channel estimates to reduce noise by averaging the time domain channel estimates across OFDM symbols to generate filtered time domain channel estimates
5. Threshold and truncate the filtered time domain channel estimates to remove noisy taps to generate thresholded/truncated/filtered time domain channel estimates (Threshold refers to the energy level to which the channel taps are compared to. Taps above the threshold are passed through while those below the threshold are zeroed out. In one example, the threshold determination is based on estimates of the macro, venue and interference signal power levels.)
6. Perform a FFT on the thresholded/truncated/filtered time domain channel estimates to obtained improved frequency domain channel estimates
7. Scramble the improved frequency domain channel estimate with the macro pilot to obtain estimated macro pilot given by: H_{M,est}(k)·P_{M}(k)
8. Cancel the estimated macro pilot by subtracting the estimated macro pilot from R(k) to obtain an input venue signal at the input of the venue signal decoder
   The second step is to obtain the venue-cast contents by decoding the input venue signal. In one example, a venue channel estimate can be obtained by an analogous process described for the cancellation of the macro pilot. The venue channel estimate may be used in the decoding of the input venue signal.

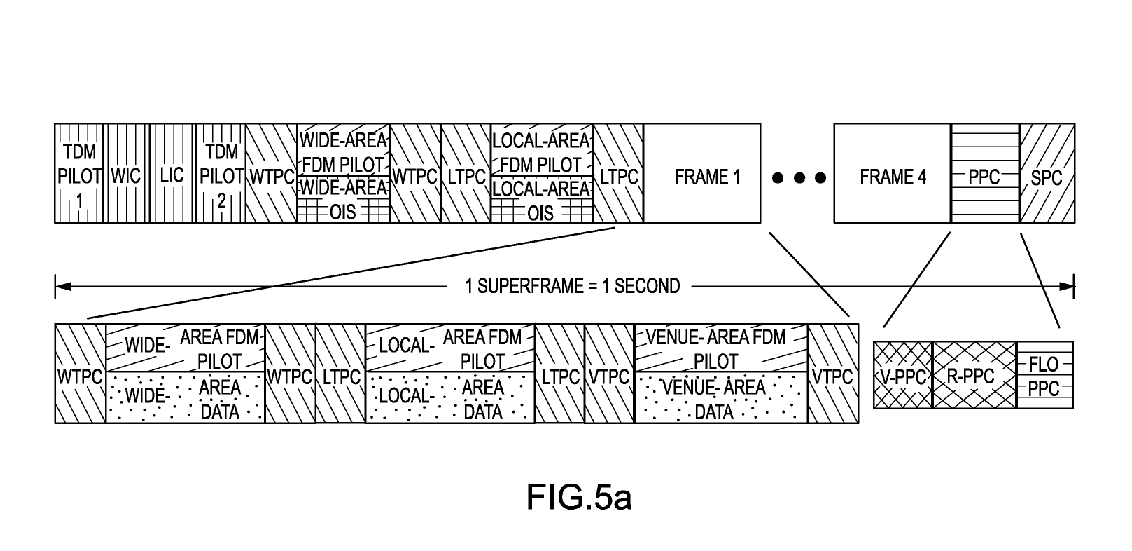

FIG. 6 illustrates an example flow diagram for supporting in-band venue-cast on a FLO network using pilot interference cancellation from the viewpoint of a receiving device. In block 610, receive a waveform with macro-cast contents introduced into a first symbol space for wide area and local area services in a superframe and venue-cast contents introduced into a second symbol space in the superframe. In one example, the waveform includes pilots in the second symbol space which are transmitted by a macro transmitter to a receiving device. The venue-cast contents are transmitted by a venue transmitter, different from the macro transmitter, to the receiving device.

Following block 610, in block 620, perform pilot interference cancellation to null the pilots in the second symbol space to allow extraction of the venue-cast contents. And in block 630, extract the venue-cast contents introduced into a second symbol space for pilots in the superframe, wherein the second symbol space is different from the first symbol space. In one aspect, the extracted venue cast contents are decoded for presentation, for example, on a display in a receiving device.

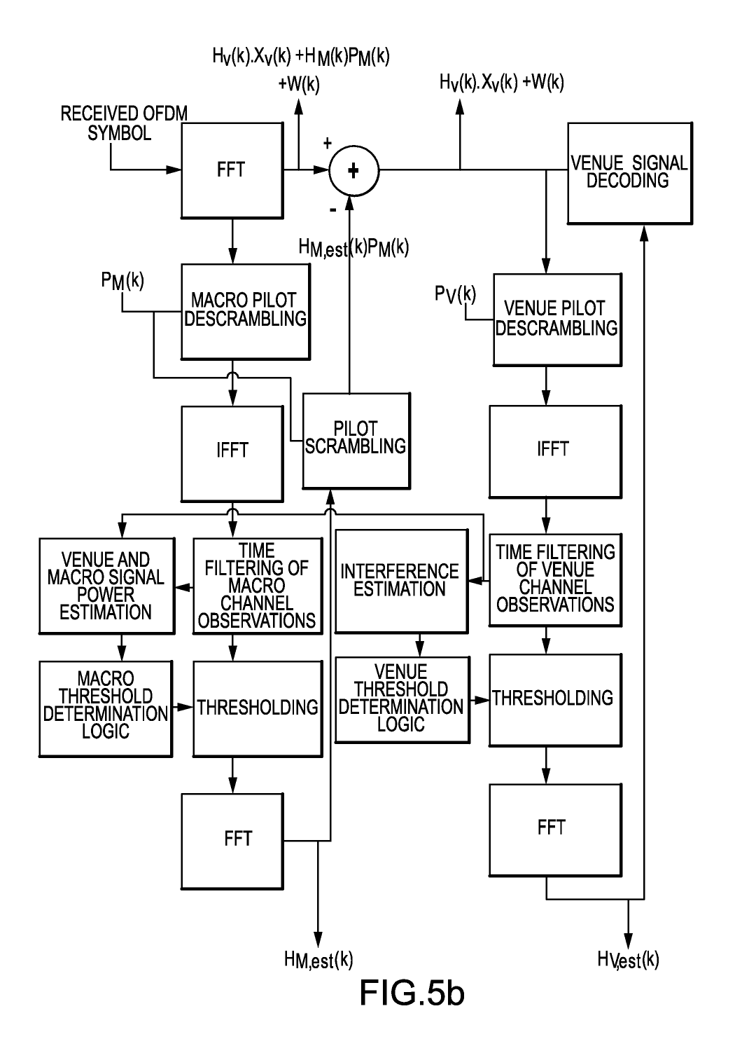

FIG. 7 illustrates an example flow diagram for supporting in-band venue-cast on a FLO network using pilot interference cancellation from the viewpoint of a venue transmitter. In block 710, determine a symbol space of a superframe where pilots associated with macro transmission are scheduled for transmission. Following block 710, in block 720, introduce venue-cast contents into the symbol space of the superframe to form a waveform. And, in block 730, transmit the waveform to a predetermined venue site.

One skilled in the art would understand that the steps disclosed in the example flow diagrams in FIGS. 6 and 7 can be interchanged in their order without departing from the scope and spirit of the present disclosure. Also, one skilled in the art would understand that the steps illustrated in the flow diagram are not exclusive and other steps may be included or one or more of the steps in the example flow diagram may be deleted without affecting the scope and spirit of the present disclosure.

Those of skill would further appreciate that the various illustrative components, logical blocks, modules, circuits, and/or algorithm steps described in connection with the examples disclosed herein may be implemented as electronic hardware, firmware, computer software, or combinations thereof. To clearly illustrate this interchangeability of hardware, firmware and software, various illustrative components, blocks, modules, circuits, and/or algorithm steps have been described above generally in terms of their functionality. Whether such functionality is implemented as hardware, firmware or software depends upon the particular application and design constraints imposed on the overall system. Skilled artisans may implement the described functionality in varying ways for each particular application, but such implementation decisions should not be interpreted as causing a departure from the scope or spirit of the present disclosure.

For example, for a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described therein, or a combination thereof. With software, the implementation may be through modules (e.g., procedures, functions, etc.) that perform the functions described therein. The software codes may be stored in memory units and executed by a processor unit. Additionally, the various illustrative flow diagrams, logical blocks, modules and/or algorithm steps described herein may also be coded as computer-readable instructions carried on any computer-readable medium known in the art or implemented in any computer program product known in the art.

In one or more examples, the steps or functions described herein may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

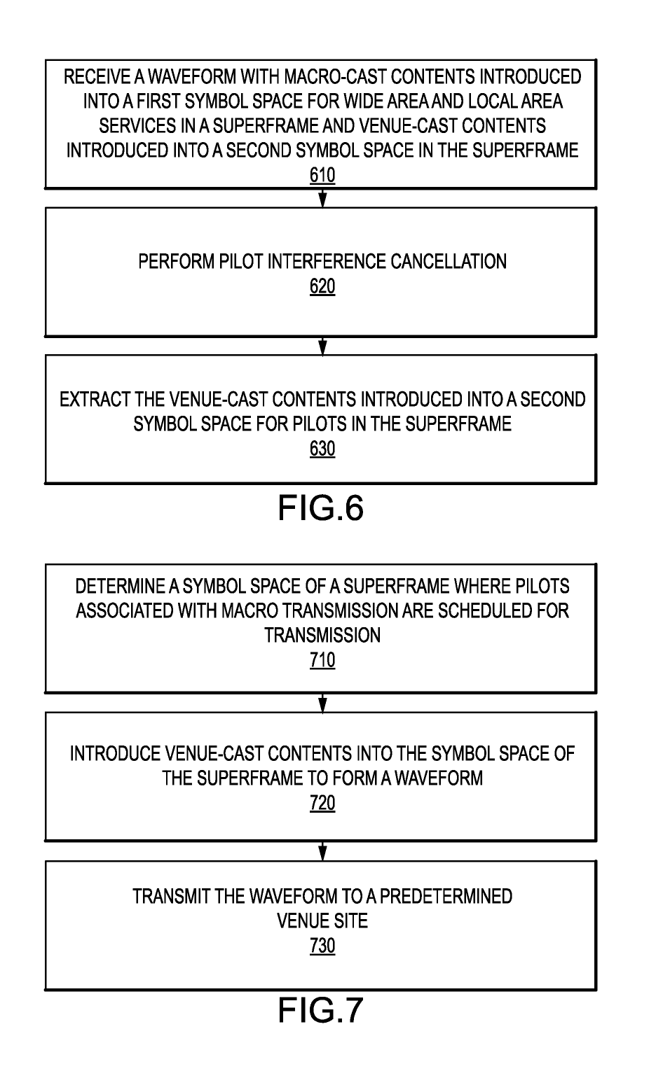

In one example, the illustrative components, flow diagrams, logical blocks, modules and/or algorithm steps described herein are implemented or performed with one or more processors. In one aspect, a processor is coupled with a memory which stores data, metadata, program instructions, etc. to be executed by the processor for implementing or performing the various flow diagrams, logical blocks and/or modules described herein. FIG. 8 illustrates an example of a device 800 comprising a processor 810 in communication with a memory 820 for executing the processes for supporting in-band venue-cast on a FLO network using pilot interference cancellation. In one example, the device 800 is used to implement the algorithms illustrated in FIGS. 6 and 7. In one aspect, the memory 820 is located within the processor 810. In another aspect, the memory 820 is external to the processor 810. In one aspect, the processor includes circuitry for implementing or performing the various flow diagrams, logical blocks and/or modules described herein.

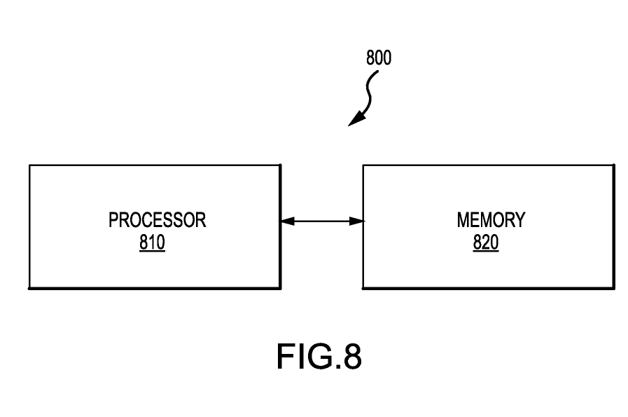

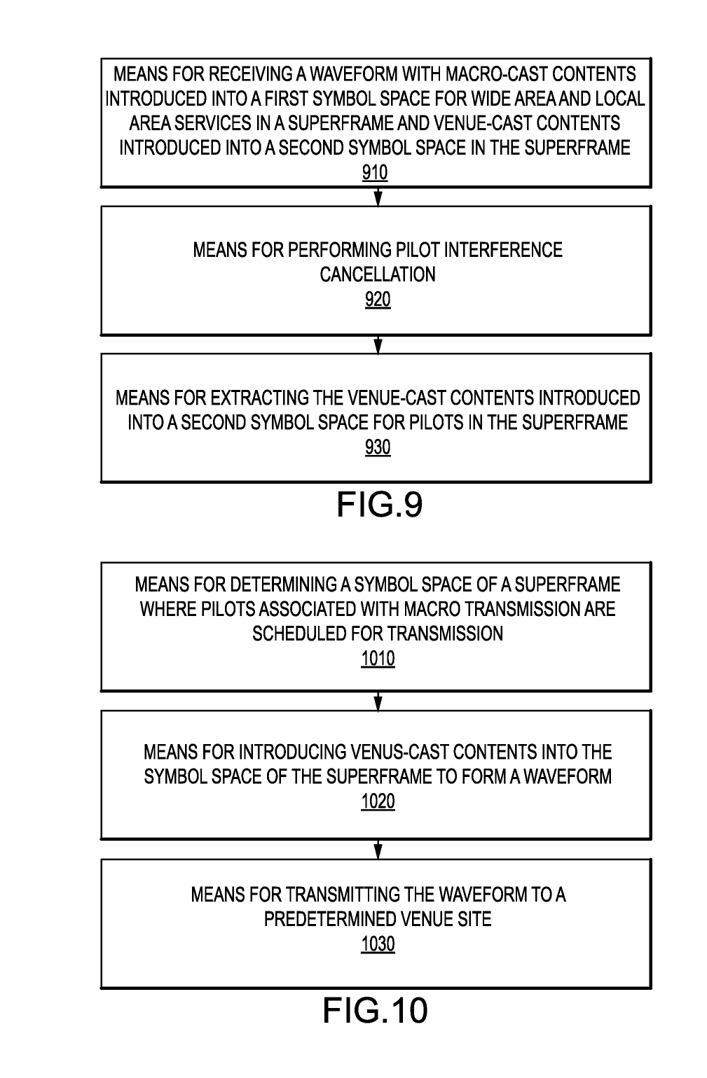

FIGS. 9 and 10 illustrate two examples of devices 900 and 1000 suitable for supporting in-band venue-cast on a FLO network using pilot interference cancellation. In one aspect, the device 900 is implemented by at least one processor comprising one or more modules configured to provide different aspects of supporting in-band venue-cast on a FLO network using pilot interference cancellation as described herein in blocks 910, 920 and 930. For example, each module comprises hardware, firmware, software, or any combination thereof. In one aspect, the device 900 is also implemented by at least one memory in communication with the at least one processor.

In one aspect, the device 1000 is implemented by at least one processor comprising one or more modules configured to provide different aspects of supporting in-band venue-cast on a FLO network using pilot interference cancellation as described herein in blocks 1010, 1020 and 1030. For example, each module comprises hardware, firmware, software, or any combination thereof. In one aspect, the device 1000 is also implemented by at least one memory in communication with the at least one processor.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure.

1. A method for supporting in-band venue-cast on a FLO network using pilot interference cancellation comprising:
receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter;
performing pilot interference cancellation to null the at least one pilot signal in the second symbol space; and
extracting the venue-cast contents from the received waveform.

2. The method of claim 1 further comprising decoding the extracted venue-cast contents for presentation.

3. The method of claim 2 wherein the presentation is made on a display of a receiving device.

4. The method of claim 2 further comprising decoding the macro-cast contents for presentation.

5. The method of claim 1 further comprising receiving in the second symbol space a predetermined pattern designated as scrambled pilots.

6. The method of claim 5 wherein the predetermined pattern includes a position pilot channel (PPC) for determining the absence or presence of the venue-cast contents.

7. The method of claim 6 wherein the position pilot channel comprises a network position pilot channel (NETWORK-PPC) associated with a macro transmitter and a venue position pilot channel (VENUE-PPC) associated with a venue transmitter.

8. The method of claim 7 wherein the venue position pilot channel (VENUE-PPC) comprises a V-PPC symbol dedicated for the transmission of a venue transmitter identification.

9. The method of claim 8 wherein the V-PPC symbol is used to determine a scrambling sequence used for venue transmission and the absence or presence of the venue-cast contents.

10. The method of claim 8 further comprising determining the presence of the venue-cast contents using the V-PPC symbol.

11. The method of claim 7 wherein the venue position pilot channel (VENUE-PPC) comprises a R-PPC symbol used for transmitting venue overhead information.

12. The method of claim 11 wherein the venue overhead information is included with the venue-cast contents.

13. The method of claim 11 wherein the R-PPC symbol contains information on the starting point of the second symbol space in the superframe.

14. The method of claim 1 wherein interference cancellation is performed in the physical layer of a networking protocol stack.

15. The method of claim 1 wherein the step of performing pilot interference cancellation comprises:
a) obtaining a time domain channel estimate from the waveform;
b) filtering the time domain channel estimate to obtain a filtered time domain channel estimate;
c) thresholding and truncating the filtered time domain channel estimate to obtained a thresholded/truncated/filtered time domain channel estimate;
d) performing a Fast Fourier Transform (FFT) on the thresholded/truncated/filtered time domain channel estimate to obtain a frequency domain channel estimate;
e) scrambling the frequency domain channel estimate to obtain an estimated macro pilot; and
f) canceling the estimated macro pilot from the waveform.

16. A method for supporting in-band venue-cast on a FLO network using pilot interference cancellation comprising:
determining a symbol space of a superframe where pilots associated with macro transmission are scheduled for transmission;
introducing venue-cast contents into the symbol space of the superframe to form a waveform; and
transmitting the waveform to a predetermined venue site.

17. A receiving device for supporting in-band venue-cast on a FLO network using pilot interference cancellation comprising:
a receiver using an antenna for receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter;
a memory unit coupled to the receiver for storing the waveform; and
a processor coupled with the memory unit, the processor for performing pilot interference cancellation to null the at least one pilot signal in the second symbol space, and for extracting the venue-cast contents from the received waveform.

18. The receiving device of claim 17 further comprising a first demodulator coupled to the processor, the first demodulator decodes the extracted venue-cast contents for presentation.

19. The receiving device of claim 18 wherein the presentation is made on a display of the receiving device.

20. The receiving device of claim 18 further comprising a second demodulator coupled to the processor, the second demodulator decodes the macro-cast contents for presentation.

21. The receiving device of claim 17 wherein the receiver uses the antenna to receive in the second symbol space a predetermined pattern designated as scrambled pilots.

22. The receiving device of claim 21 wherein the predetermined pattern includes a position pilot channel (PPC) for determining the absence or presence of the venue-cast contents.

23. The receiving device of claim 22 wherein the position pilot channel comprises a network position pilot channel (NETWORK-PPC) associated with a macro transmitter and a venue position pilot channel (VENUE-PPC) associated with a venue transmitter.

24. The receiving device of claim 23 wherein the venue position pilot channel (VENUE-PPC) comprises a V-PPC symbol dedicated for the transmission of a venue transmitter identification.

25. The receiving device of claim 24 wherein the V-PPC symbol is used by the processor to determine a scrambling sequence used for venue transmission and the absence or presence of the venue-cast contents.

26. The receiving device of claim 24 wherein the processor determines the presence of the venue-cast contents using the V-PPC symbol.

27. The receiving device of claim 23 wherein the venue position pilot channel (VENUE-PPC) comprises a R-PPC symbol used for transmitting venue overhead information.

28. The receiving device of claim 27 wherein the venue overhead information is included with the venue-cast contents.

29. The receiving device of claim 27 wherein the R-PPC symbol contains information on the starting point of the second symbol space in the superframe.

30. The receiving device of claim 17 wherein the processor performs interference cancellation in the physical layer of a networking protocol stack.

31. The receiving device of claim 17 wherein the processor for performing the pilot interference cancellation further performs the following steps:
a) obtaining a time domain channel estimate from the waveform;
b) filtering the time domain channel estimate to obtain a filtered time domain channel estimate;
c) thresholding and truncating the filtered time domain channel estimate to obtained a thresholded/truncated/filtered time domain channel estimate;
d) performing a Fast Fourier Transform (FFT) on the thresholded/truncated/filtered time domain channel estimate to obtain a frequency domain channel estimate;
e) scrambling the frequency domain channel estimate to obtain an estimated macro pilot; and
f) canceling the estimated macro pilot from the waveform.

32. A venue transmitter for supporting in-band venue-cast on a FLO network using pilot interference cancellation comprising:
a processor for determining a symbol space of a superframe where pilots associated with macro transmission are scheduled for transmission, and for introducing venue-cast contents into the symbol space of the superframe to form a waveform; and
an antenna coupled to the processor for transmitting the waveform to a predetermined venue site.

33. A receiving apparatus for supporting in-band venue-cast on a FLO network using pilot interference cancellation comprising:
means for receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter;
means for performing pilot interference cancellation to null the at least one pilot signal in the second symbol space; and
means for extracting the venue-cast contents from the received waveform.

34. The receiving apparatus of claim 33 further comprising means for decoding the extracted venue-cast contents for presentation.

35. The receiving apparatus of claim 34 wherein the presentation is made on a display of the receiving apparatus.

36. The receiving apparatus of claim 34 further comprising means for decoding the macro-cast contents for presentation.

37. The receiving apparatus of claim 33 further comprising means for receiving in the second symbol space a predetermined pattern designated as scrambled pilots.

38. The receiving apparatus of claim 37 wherein the predetermined pattern includes a position pilot channel (PPC) for determining the absence or presence of the venue-cast contents.

39. The receiving apparatus of claim 38 wherein the position pilot channel comprises a network position pilot channel (NETWORK-PPC) associated with a macro transmitter and a venue position pilot channel (VENUE-PPC) associated with a venue transmitter.

40. The receiving apparatus of claim 39 wherein the venue position pilot channel (VENUE-PPC) comprises a V-PPC symbol dedicated for the transmission of a venue transmitter identification.

41. The receiving apparatus of claim 40 wherein the V-PPC symbol is used to determine a scrambling sequence used for venue transmission and the absence or presence of the venue-cast contents.

42. The receiving apparatus of claim 40 further comprising means for determining the presence of the venue-cast contents using the V-PPC symbol.

43. The receiving apparatus of claim 39 wherein the venue position pilot channel (VENUE-PPC) comprises a R-PPC symbol used for transmitting venue overhead information.

44. The receiving apparatus of claim 43 wherein the venue overhead information is included with the venue-cast contents.

45. The receiving apparatus of claim 43 wherein the R-PPC symbol contains information on the starting point of the second symbol space in the superframe.

46. The receiving apparatus of claim 33 further comprising means for performing interference cancellation in the physical layer of a networking protocol stack.

47. The receiving apparatus of claim 33 wherein the means for performing pilot interference cancellation further comprises
a) means for obtaining a time domain channel estimate from the waveform;
b) means for filtering the time domain channel estimate to obtain a filtered time domain channel estimate;
c) means for thresholding and truncating the filtered time domain channel estimate to obtained a thresholded/truncated/filtered time domain channel estimate;
d) means for performing a Fast Fourier Transform (FFT) on the thresholded/truncated/filtered time domain channel estimate to obtain a frequency domain channel estimate;
e) means for scrambling the frequency domain channel estimate to obtain an estimated macro pilot; and
f) means for canceling the estimated macro pilot from the waveform.

48. A transmitting apparatus for supporting in-band venue-cast on a FLO network using pilot interference cancellation comprising:
means for determining a symbol space of a superframe where pilots associated with macro transmission are scheduled for transmission;
means for introducing venue-cast contents into the symbol space of the superframe to form a waveform; and
means for transmitting the waveform to a predetermined venue site.

49. A computer-readable medium storing a computer program, wherein execution of the computer program is for:
receiving a waveform with macro-cast contents introduced into a first symbol space in a superframe for wide area and local area services, at least one pilot signal introduced into a second symbol space in the superframe and venue-cast contents also introduced into the second symbol space in the superframe, wherein the macro-cast contents and the at least one pilot signal are transmitted by a macro transmitter, and wherein the venue-cast contents are transmitted by a venue transmitter which is different from the macro transmitter;
performing pilot interference cancellation to null the at least one pilot signal in the second symbol space; and
extracting the venue-cast contents from the received waveform.

50. A computer-readable medium storing a computer program, wherein execution of the computer program is for:
determining a symbol space of a superframe where pilots associated with macro transmission are scheduled for transmission;
introducing venue-cast contents into the symbol space of the superframe to form a waveform; and
transmitting the waveform to a predetermined venue site.
